(19) United States
(12) Patent Application Publication
(10) Pub. No.: US 2008/0105984 A1
(43) Pub. Date: May 8, 2008

(54) SEMICONDUCTOR CHIP STACK PACKAGE WITH REINFORCING MEMBER FOR PREVENTING PACKAGE WARPAGE CONNECTED TO SUBSTRATE

(75) Inventor: Min-Ho LEE, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/933,067

(22) Filed: Oct. 31, 2007

(30) Foreign Application Priority Data
Nov. 3, 2006 (KR) 2006-0108383

(51) Int. Cl. H01L 23/48

(52) U.S. Cl. 257/777; 257/686; 257/E23.01

(57) ABSTRACT

Provided is a semiconductor chip stack package with a reinforcing member connected to a substrate for preventing package warpage. The semiconductor chip stack package includes a first substrate including first circuit patterns on one surface thereof; a first unit semiconductor chip including a plurality of semiconductor chips stacked vertically on the first substrate and including first connection pads electrically connected to the first circuit patterns of the first substrate on one surface thereof; and a first reinforcing member arranged over the first unit semiconductor chip and including first circuit patterns on one surface thereof. The top semiconductor chip in the first unit semiconductor chip further includes first subsidiary connection pads connected to the first connection pads. The first circuit patterns of the first reinforcing member are electrically connected to the first circuit patterns of the first substrate via the first subsidiary connection pads of the top semiconductor chip.

### CROSS-REFERENCE TO RELATED PATENT APPLICATION

This application claims priority under 35 USC § 119 to Korean Patent Application No. 10-2006-0108383, filed on Nov. 3, 2006 in the Korean Intellectual Property Office, the disclosure of which is incorporated herein in its entirety by reference.

### BACKGROUND

1. Technical Field

The present invention relates to a semiconductor package, and more particularly, to a semiconductor chip stack package with a reinforcing member connected to a substrate for preventing package warpage.

2. Description of the Related Art

As electronic devices such as portable personal computers (PCs) and mobile telephones get lighter, slimmer, and more compact, they need smaller and more multifunctional semiconductor devices. The integration density of a semiconductor device increases with the capacity and function of the semiconductor package. To achieve very high integration density, a semiconductor chip stack package contains a plurality of stacked semiconductor chips mounted on a substrate, resulting in one unit semiconductor chip package. The semiconductor chip stack package gives advantages in size, weight and mounting area compared to a number of unit semiconductor chip packages each containing one semiconductor chip.

However, semiconductor chip stack packages present many manufacturing challenges. When semiconductor chips are adhered to a substrate such as a printed circuit board (PCB) of a semiconductor chip stack package by thermally compressing conductive balls therebetween, the substrate is bent into a convex form. This is a form of package warpage. Package warpage is more severe when a thin wafer of less than 50 μm is used because there is less semiconductor material in the package to oppose the warpage. Also, in a wafer level package, a defect is generated when individual semiconductor chips are separated, thus degrading the production yield. Finally, in a package on package (POP), having a semiconductor package stacked on another semiconductor package, high integration in a small space is difficult to achieve. The present invention addresses these and other disadvantages of the conventional art.

### SUMMARY

The present invention provides a semiconductor chip stack package with a reinforcing member connected to a substrate for preventing package warpage.

According to an aspect of the present invention, there is provided a semiconductor chip stack package including a first substrate having first circuit patterns on one surface thereof; a first unit semiconductor chip including a plurality of semiconductor chips stacked vertically on the first substrate and including first connection pads electrically connected to the first circuit patterns of the first substrate on one surface thereof; and a first reinforcing member arranged over the first unit semiconductor chip and including first circuit patterns on one surface thereof. The top semiconductor chip in the first unit semiconductor chip further includes first subsidiary connection pads connected to the first connection pads. The first circuit patterns of the first reinforcing member are electrically connected to the first circuit patterns of the first substrate via the first subsidiary connection pads of the top semiconductor chip.

The semiconductor chip stack package according to some embodiments of the present invention includes a reinforcing member made of a similar material as the substrate to prevent the package warpage, thus improving production yield and aiding the increased integration of semiconductor devices. In addition, since the reinforcing member is used as a connection member when a semiconductor package is stacked on another semiconductor package, the overall semiconductor package can be smaller, thinner and lighter.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of a semiconductor chip stack package including a reinforcing member for preventing package warpage according to a first embodiment of the present invention;

FIG. 2 is a cross-sectional view of a connection between a connection pad and a subsidiary connection pad in the semiconductor chip stack package of FIG. 1;

FIG. 3 is a cross-sectional view of a semiconductor chip stack package including a reinforcing member for preventing package warpage according to a second embodiment of the present invention;

FIG. 4 is a cross-sectional view of a semiconductor chip stack package including a reinforcing member for preventing package warpage according to a third embodiment of the present invention;

FIG. 5 is a cross-sectional view of a semiconductor chip stack package including a reinforcing member for preventing package warpage according to a fourth embodiment of the present invention;

FIG. 6 is a cross-sectional view of a semiconductor chip stack package including a reinforcing member for preventing package warpage according to a fifth embodiment of the present invention;

FIG. 7 is a cross-sectional view of a semiconductor chip stack package including a reinforcing member for preventing package warpage according to a sixth embodiment of the present invention;

FIGS. 8A and 8B are cross-sectional views of exemplary connection terminals in the semiconductor chip stack package of FIG. 7;

FIG. 9 is a cross-sectional view of a semiconductor chip stack package including a reinforcing member for preventing package warpage according to a seventh embodiment of the present invention;

FIG. 10 is a cross-sectional view of a semiconductor chip stack package including a reinforcing member for preventing package warpage according to an eighth embodiment of the present invention;

FIG. 11 is a cross-sectional view of a semiconductor chip stack package including a reinforcing member for preventing package warpage according to a ninth embodiment of the present invention; and

FIG. 12 is a cross-sectional view of a semiconductor chip stack package including a reinforcing member for preventing package warpage according to a tenth embodiment of the present invention.

### DETAILED DESCRIPTION

The present invention will now be described more fully with reference to the accompanying drawings, in which preferred embodiments of the invention are shown. This invention may, however, be embodied in many different forms, and should not be construed as being limited to the embodiments set forth herein. Rather, these embodiments are provided so that this disclosure will be thorough and complete, and will fully convey the scope of the invention to those skilled in the art. Like reference numbers refer to like elements throughout the specification.

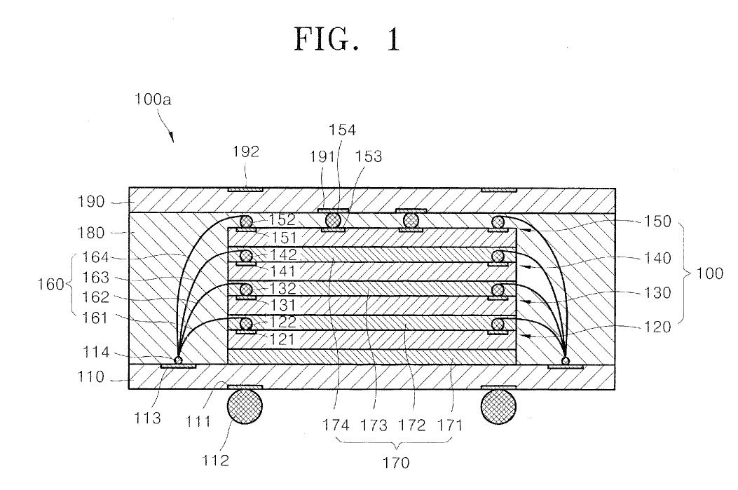

FIG. 1 is a cross-sectional view of a fine-pitch ball grid array (FBGA) type semiconductor chip stack package according to a first embodiment of the present invention. Referring to FIG. 1, a semiconductor chip stack package 100a includes a substrate 110, a plurality of semiconductor chips 120, 130, 140 and 150, and a reinforcing member 190 arranged over the top semiconductor chip 150 of the plurality of semiconductor chips 120, 130, 140 and 150. The substrate 110 may be a printed circuit substrate. The substrate 110 includes a plurality of first circuit patterns 111 arranged on one surface thereof, and a plurality of second circuit patterns 113 arranged on the other surface thereof. The first circuit patterns 111 and the second circuit patterns 113 may be electrically connected via circuit interconnections (not shown) in the substrate 110. A plurality of external connection terminals 112 are arranged on the first circuit patterns 111. The external connection terminals 112 may be conductive balls such as solder balls. A plurality of internal connection terminals 114 are arranged on the second circuit patterns 113. The internal connection terminals 114 may be conductive balls.

The plurality of semiconductor chips 120, 130, 140 and 150 are stacked vertically on the substrate 110, resulting in a unit semiconductor chip 100. The semiconductor chips 120, 130, 140 and 150 are adhered by an adhesive 170 and stacked so that their connection pads 121, 131, 141 and 151 face upward. The bottom semiconductor chip 120 is adhered to the surface of the substrate 110 by an adhesive 171, and the upper semiconductor chips 130, 140 and 150 are respectively adhered to the lower semiconductor chips 120, 130 and 140 by the adhesives 172, 173 and 174. Each of the semiconductor chips 120, 130, 140 and 150 has the plurality of connection pads 121, 131, 141 and 151 on one surface thereof, and connection terminals 122, 132, 142 and 152 are respectively arranged on the connection pads. The connection terminals 122, 132, 142 and 152 may include conductive balls.

The connection terminals 122, 132, 142 and 152 are wire-bonded to the internal connection terminals 114 of the substrate 110 via wires 161, 162, 163 and 164, respectively. A plurality of subsidiary connection pads 153 are arranged in a central portion of one surface of the top semiconductor chip 150, and a plurality of subsidiary connection terminals 154 are arranged on the plurality of subsidiary connection pads 153. The subsidiary connection pads 153 are formed through a redistribution process. The subsidiary connection terminals 154 may include conductive balls. The unit semiconductor chip 100, the wires 160, and the connection terminals 114, 152 and 154 are sealed between the reinforcing member 190 and the substrate 110 by an encapsulant 180 for protection from the external environment.

In the unit semiconductor chip 100, the top semiconductor chip 150 may be a chip for connection, not a semiconductor memory chip. In this case, the top semiconductor chip 150 includes only the connection pads 151 and the subsidiary connection pads 153 formed through the redistribution process, in order only to couple the unit semiconductor chip 100 to the reinforcing member 190.

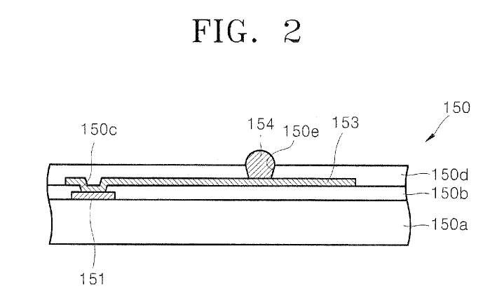

FIG. 2 is a cross-sectional view of a connection between a connection pad and a subsidiary connection pad in the semiconductor chip stack package of FIG. 1. Referring to FIG. 2, a connection pad 151 is formed on one surface of a wafer 150a. The one surface of the wafer 150a refers to a surface on which various semiconductor devices (not shown) are integrated through a semiconductor fabrication process. The connection pad 151 electrically connects the semiconductor devices to an external device, and may include, for example a metal pad such as an A1 pad. A first insulating layer 150b is formed on the surface of the wafer 150a and the connection pad 151. The first insulating layer 150b includes an opening 150c that exposes a portion of the connection pad 151.

A subsidiary connection pad 153 connected to the connection pad 151 via the opening 150c is formed on the first insulating layer 150b through a redistribution process. The subsidiary connection pad 153 may include a metal pad such as Cu or Cu/Ni/Ti. A second insulating layer 150d is formed on the first insulating layer 150b and the subsidiary connection pad 153. The second insulating layer 150d includes an opening 150e that exposes a portion of the subsidiary connection pad 153. A subsidiary connection terminal 154 is adhered to the subsidiary connection pad 153 exposed through the opening 150e.

Referring again to FIG. 1, the reinforcing member 190 includes a material similar to the substrate 110 in coefficient of thermal contraction/expansion, glass transition temperature T_{g}, and the like. The reinforcing member 190 may include a printed circuit substrate. The reinforcing member 190 includes a plurality of first circuit patterns 191 arranged on one surface thereof and a plurality of second circuit patterns 192 arranged on the other surface thereof. The first circuit patterns 191 and the second circuit patterns 192 may be electrically connected via circuit interconnections (not shown) arranged in the reinforcing member 190. The first circuit patterns 191 are flip-chip bonded and electrically connected to the subsidiary connection terminals 154 of the top semiconductor chip 150. Accordingly, the first circuit patterns 191 of the reinforcing member 190 are electrically connected to the internal connection terminals 114 of the substrate 110. A plurality of external connection terminals (not shown), e.g. conductive balls, may be adhered to the second circuit patterns 192.

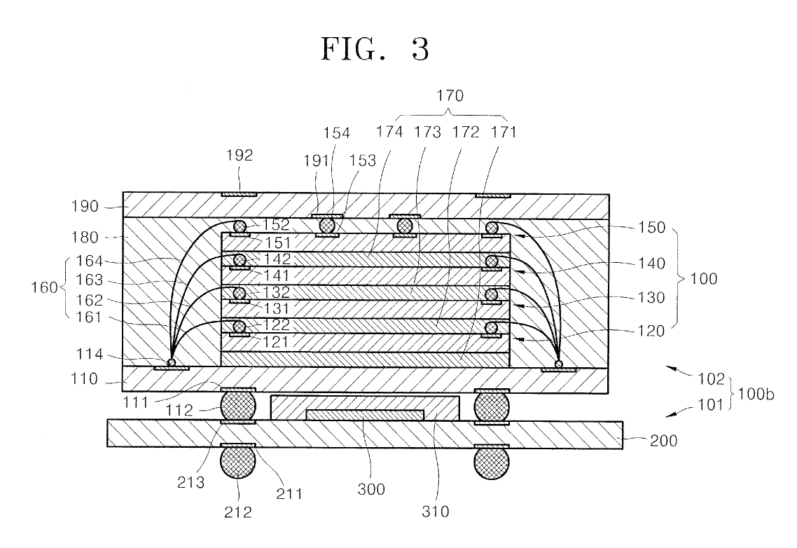

FIG. 3 is a cross-sectional view of a package on package (POP) type semiconductor chip stack package according to a second embodiment of the present invention. Referring to FIG. 3, a semiconductor chip stack package 100b includes, for example, a first semiconductor package 101 on which is mounted a logic chip 300, and a second semiconductor package 102 stacked on the first semiconductor package 101. The first semiconductor package 101 includes a substrate 200. The substrate 200 may include a printed circuit substrate. The substrate 200 includes a plurality of first circuit patterns 211 arranged on one surface thereof and a plurality of second circuit patterns 213 arranged on the other surface thereof. The first circuit patterns 111 and the second circuit patterns 113 may be electrically connected via circuit interconnections (not shown) in the substrate 210. A plurality of first connection terminals 212 are arranged on the first circuit patterns 211. The first connection terminals 212 may include conductive balls.

Although not shown in FIG. 3, the logic chip 300 may be adhered to the substrate 200 by an adhesive, and may be electrically connected to the substrate 200 by wires or flip-chip bonding. The logic chip 300 and the wires are coated with an encapsulant 310. The second semiconductor package 102 has the same structure as the semiconductor package 100a shown in FIG. 1. External connection terminals 112 of the second semiconductor package 102 are electrically connected to the second circuit patterns 213 of the substrate 200, so that the semiconductor chips 120, 130, 140 and 150 are electrically connected to the logic chip 300. The semiconductor chips 120, 130, 140 and 150 may include semiconductor memory chips.

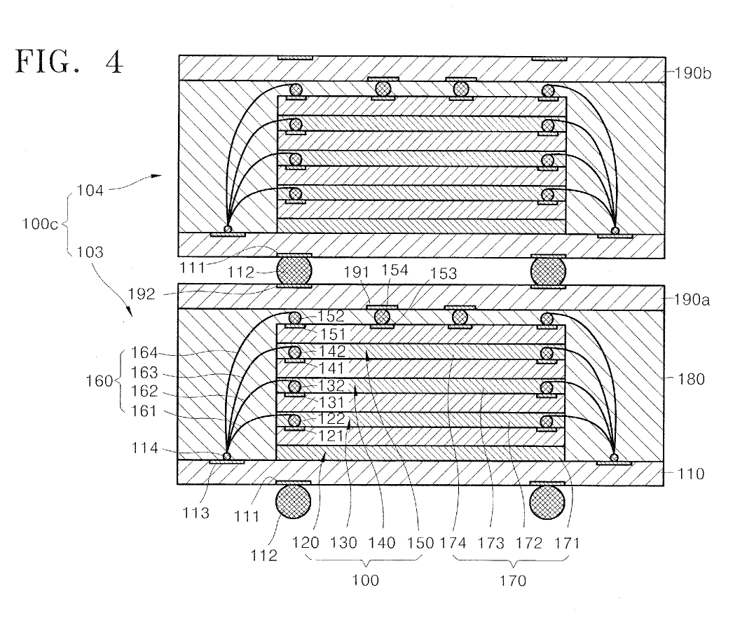

FIG. 4 is a cross-sectional view of a POP type semiconductor chip stack package according to a third embodiment of the present invention. Referring to FIG. 4, a semiconductor chip stack package 100c includes a first semiconductor package 103 and a second semiconductor package 104 stacked on the first semiconductor package 103. The first and second semiconductor packages 103 and 104 have the same structure as the semiconductor chip stack package 100a shown in FIG. 1, and are stacked vertically so that their connection pads 121, 131, 141 and 151 face upward. Second circuit patterns 192 of a reinforcing member 190a of the first semiconductor package 103 are flip-chip bonded and electrically connected to external connection terminals 112 of the second semiconductor package 104. The second circuit patterns 192 of the reinforcing member 190a of the first semiconductor package 103 may be directly flip-chip bonded and electrically connected to first circuit patterns 111 of the substrate 110 of the second semiconductor package 104.

The first reinforcing member 190a is arranged between the first semiconductor package 103 and the second semiconductor package 104 and serves as a connection member that not only prevents package warpage but also electrically connects the first semiconductor package 103 to the second semiconductor package 104. Accordingly, the semiconductor chips 120, 130, 140 and 150 of the first and second semiconductor packages 103 and 104 are connected to the substrate 110 of the first semiconductor package 103 via the reinforcing member 190a. The second semiconductor package 104 does not necessarily include a second reinforcing member 190b. In at least one of the first semiconductor package 103 and the second semiconductor package 104, the top semiconductor chip 150 in the unit semiconductor chip 100 may be a chip for connection, not a semiconductor memory chip. In this case, the top semiconductor chip 150 may include only connection pads 151 and subsidiary connection pads 153 formed through a redistribution process, in order to only connect the unit semiconductor chip 100 to the reinforcing members 190a and 190b.

As another example, the second semiconductor package 104 may be turned over so that the first semiconductor package 103 and the second semiconductor package 104 are stacked opposite to each other. The second semiconductor package 104 may be stacked on the first semiconductor package 103 so that the reinforcing member 190a of the first semiconductor package 103 is brought into direct contact with the second connection pads 192 of the reinforcing member 190b of the second semiconductor package 104. Alternatively, connection terminals can be located on the second connection pads 192 of the reinforcing member 190a or 190b so that the first semiconductor package 103 and the second semiconductor package 104 are stacked in contact with each other via the connection terminals. Further, the semiconductor chip stack package 300c may be stacked on a substrate having a logic chip mounted thereon, as shown in FIG. 3.

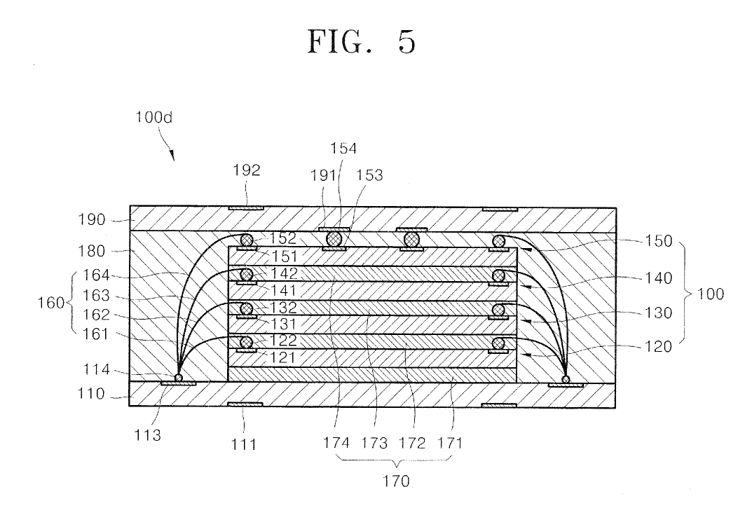

FIG. 5 is a cross-sectional view of a land grid array (LGA) type semiconductor chip stack package according to a fourth embodiment of the present invention. Referring to FIG. 5, a semiconductor chip stack package 100d is the same as the semiconductor chip stack package 100a of FIG. 1 except that it does not have the external connection terminals 112. The semiconductor chip stack package 100d is electrically connected to an external device via first circuit patterns 111.

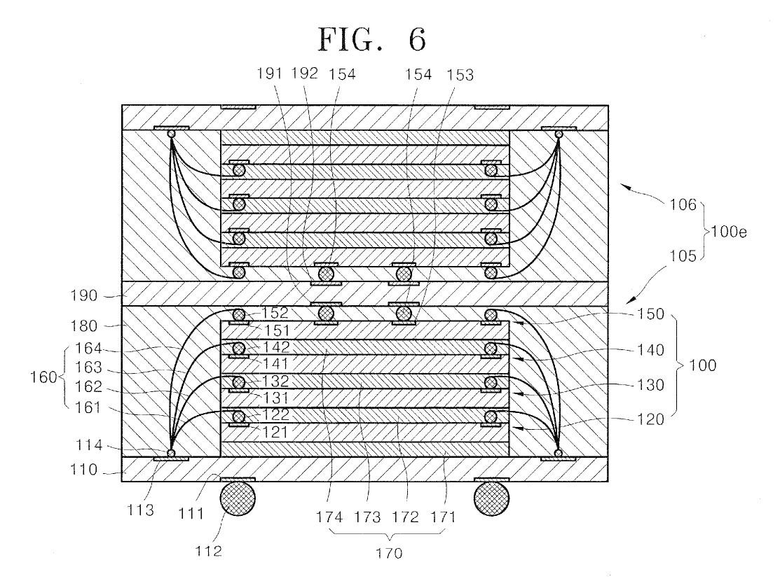

FIG. 6 is a cross-sectional view of a POP type semiconductor chip stack package according to a fifth embodiment of the present invention. Referring to FIG. 6, a semiconductor chip stack package 100e includes a first semiconductor package 105, and a second semiconductor package 106 stacked on the first semiconductor package 105. The first and second semiconductor packages 105 and 106 have the same structure as the semiconductor chip stack packages 100a and 100d shown in FIGS. 1 and 5, respectively, and are vertically stacked so that connection pads 121, 131, 141 and 151 of the first and second semiconductor packages 105 and 106 are opposite each other with a reinforcing member 190 interposed therebetween. In this case, subsidiary connection terminals 154 of the second semiconductor package 106 are connected to second circuit patterns 192 of the reinforcing member 190 of the first semiconductor package 105 without its reinforcing member. The second circuit patterns 192 of the reinforcing member 190 of the first semiconductor package 105 are arranged to correspond to the subsidiary connection terminals 154 of the second semiconductor package 106.

The reinforcing member 190 of the first semiconductor package 105 serves as a connection member that not only prevents package warpage but also electrically connects the first semiconductor package 105 to the second semiconductor package 106. Further, the semiconductor chip stack package 100e may be stacked on a substrate having a logic chip mounted thereon, as shown in FIG. 3.

FIG. 7 is a cross-sectional view of a wafer level stack package type semiconductor chip stack package according to a sixth embodiment of the present invention. Referring to FIG. 7, a semiconductor chip stack package 400a includes a substrate 410, a plurality of semiconductor chips 420, 430, 440 and 450, and a reinforcing member 490 arranged over the top of the semiconductor chip 450 of the plurality of semiconductor chips 420, 430, 440 and 450. The substrate 410 may include a printed circuit substrate. The substrate 410 includes a plurality of first circuit patterns 411 on one surface thereof and a plurality of second circuit patterns 413 on the other surface thereof. The first circuit patterns 411 and the second circuit patterns 413 may be electrically connected via circuit interconnections (not shown) arranged in the substrate 410. A plurality of external connection terminals 412 are arranged on the first circuit patterns 411. The external connection terminals 412 may include conductive balls.

The plurality of semiconductor chips 420, 430, 440 and 450 are vertically stacked on the substrate 410, resulting in a unit semiconductor chip 400. The semiconductor chips 420, 430, 440 and 450 include a plurality of vias 421, 431, 441 and 451, and connection terminals 422, 432, 442 and 452 buried in the vias 421, 431, 441 and 451. The bottom semiconductor chip 420 in the unit semiconductor chip 400 and the substrate 410 are flip-chip bonded and electrically connected to each other. The top semiconductor chip 450 and the reinforcing member 490, and the upper semiconductor chips 430, 440 and 450 and the lower semiconductor chips 420, 430 and 440 are also flip-chip bonded and electrically connected to each other. That is, the connection terminal 422 of the bottom semiconductor chip 420 is connected to the second circuit pattern 413 of the substrate 410 via a first connection member 461 and the connection terminal 452 of the top semiconductor chip 450 is connected to a first circuit pattern 491 of the reinforcing member 490 via a fifth connection member 465. The connection terminals 432, 442 and 452 of the upper semiconductor chips 430, 440 and 450 are connected respectively to the connection terminals 422, 432 and 442 of the lower semiconductor chips 420, 430, 440 via second to fourth connection members 462, 463 and 464. The first to fifth connection members 461 to 465 may include conductive balls.

The reinforcing member 490 includes a material similar to the substrate 410 in coefficient of thermal contraction/expansion, glass transition temperature T_{g}, and the like. The reinforcing member 490 may include a printed circuit substrate. The reinforcing member 490 includes a plurality of first circuit patterns 491 arranged on one surface thereof and a plurality of second circuit patterns 492 arranged on the other surface thereof. The first circuit patterns 491 and the second circuit patterns 492 may be electrically connected via circuit interconnections (not shown) arranged in the reinforcing member 490. The first circuit patterns 491 of the reinforcing member 490 are flip-chip bonded and electrically connected to the connection terminals 452 of the top semiconductor chip 450 through the fifth connection members 465. Accordingly, the first circuit patterns 491 of the reinforcing member 490 are electrically connected to the second circuit patterns 413 of the substrate 410. A plurality of external connection terminals, e.g. conductive balls, may be adhered to the second circuit patterns 492 of the reinforcing member 490. Between the reinforcing member 490 and the substrate 410, the unit semiconductor chip 400 and the connection members 461 to 465 are sealed by an encapsulant 480 to provide protection from the external environment.

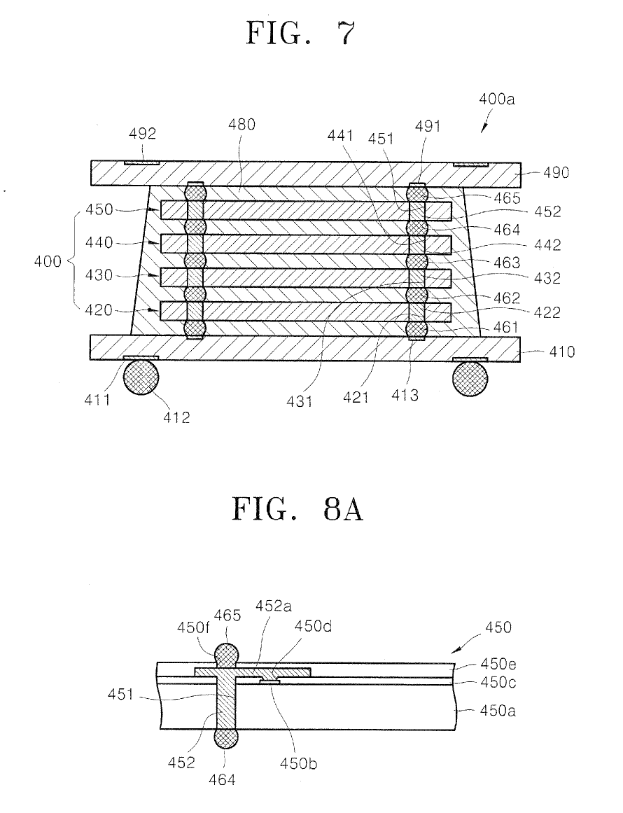

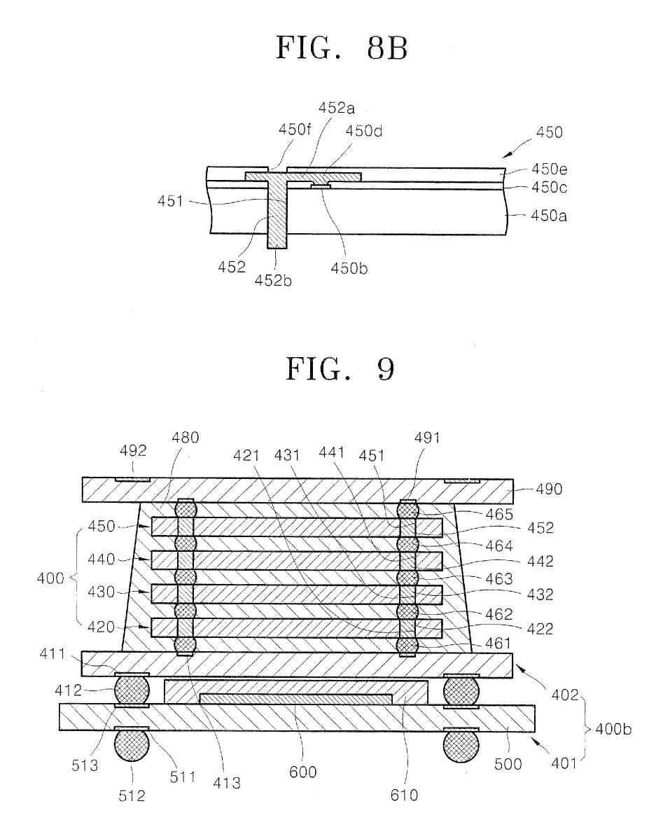

FIG. 8A shows an example of the connection terminal 452 of the top semiconductor chip 450 in the semiconductor chip stack package 400a of FIG. 7. Referring to FIG. 8A, a connection pad 450b is formed on one surface of a wafer 450a. The one surface of the wafer 450a refers to a surface on which various semiconductor devices (not shown) are integrated through a semiconductor fabrication process. The connection pad 450b electrically connects the semiconductor devices to an external device, and may include for example a metal pad such as an A1 pad. A first insulating layer 450c is formed on the one surface of the wafer 450a and the connection pad 450b. The first insulating layer 450c includes an opening 450d that exposes a portion of the connection pad 450b.

A redistribution layer 452a is formed on the first insulating layer 450c through a redistribution process for connecting the connection pad 450b to the connection terminal 452 via the opening 450d. The redistribution layer 452a may include, for example, Cu or Cu/Ni/Ti. A second insulating layer 450e is formed on the first insulating layer 450c and the redistribution layer 452a. The second insulating layer 450e includes an opening 450f that exposes a portion of the redistribution layer 452a. A connection member 465 is adhered to the redistribution layer 452a exposed through the opening 450f. The connection member 465 may be directly adhered to the connection terminal 452, not via the redistribution layer 452a. The connection terminal 452 penetrates the wafer 450a and is electrically connected to another connection member 464. Thus, the connection pad 450b is electrically connected to both the connection member 465 and to the other connection member 464.

In the semiconductor chip stack package 400a of FIG. 7, the connection terminals 422 of the bottom semiconductor chip 420 may be flip-chip bonded to the second circuit patterns 413 of the substrate 410 to make a direct connection without the first connection member 461. Furthermore, the connection terminals 432, 442 and 452 of the upper semiconductor chips 430, 440 and 450 may be flip-chip bonded directly to the connection terminals 422, 432 and 442 of the lower semiconductor chip 420, 430 and 440, without the second to fourth connection members 462, 463 and 464.

FIG. 8B shows another example of the connection terminal 452 of the top semiconductor chip 450 in the semiconductor chip stack package 400a of FIG. 7. Referring to FIG. 8B, the connection terminal 452 includes a protrusion 452b protruding from the wafer 450a and connected to the redistribution layer (see 452a) of the underlying semiconductor chip 440 via the second opening (see 450f) of the underlying semiconductor chip 440. The protrusion 452b may be directly adhered to the connection terminal 442, not via the redistribution layer of the underlying semiconductor chip 440. Similarly, the connection terminal 422 of the bottom semiconductor chip 420 includes a protrusion flip-chip bonded to the second circuit pattern 413 of the substrate 410. In the top semiconductor chip 450, the connection member 465 is arranged in the opening 450f and flip-chip bonded to the first circuit pattern 491 of the reinforcing member 490.

FIG. 9 is a cross-sectional view of a POP type semiconductor chip stack package according to a seventh embodiment of the present invention. Referring to FIG. 9, a semiconductor chip stack package 400b includes, for example, a first semiconductor package 401 on which is mounted a logic chip 600, and a second semiconductor package 402 stacked on the first semiconductor package 401. The first semiconductor package 401 includes a substrate 500, which may include a printed circuit substrate. The substrate 500 includes a plurality of first and second circuit patterns 511 and 513 arranged on its respective surfaces. A plurality of external connection terminals 512 are arranged on the first circuit patterns 511. The external connection terminals 512 may include conductive balls. The first circuit patterns 511 and the second circuit patterns 513 may be electrically connected via circuit interconnections (not shown) arranged in the substrate 500.

Although not shown in FIG. 9, the logic chip 600 may be adhered to the substrate 500 by an adhesive, and may be electrically connected to the substrate 500 by wires or flip-chip bonding. The logic chip 600 and the wires are coated with an encapsulant 610. The second semiconductor package 402 has the same structure as the semiconductor package 400a shown in FIG. 7. External connection terminals 412 of the second semiconductor package 402 are electrically connected to the second circuit patterns 513 of the substrate 500, so that the semiconductor chips 420, 430, 440 and 450 are electrically connected to the logic chip 600. The semiconductor chips 420, 430, 440 and 450 may include semiconductor memory chips.

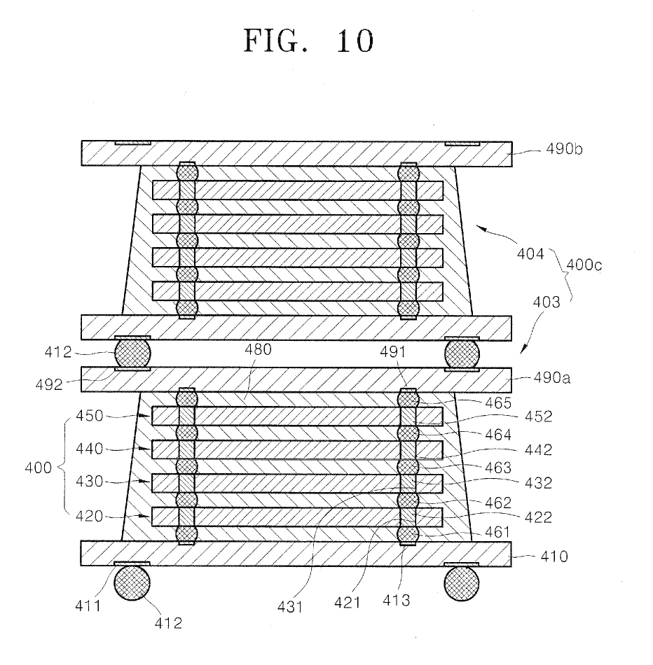

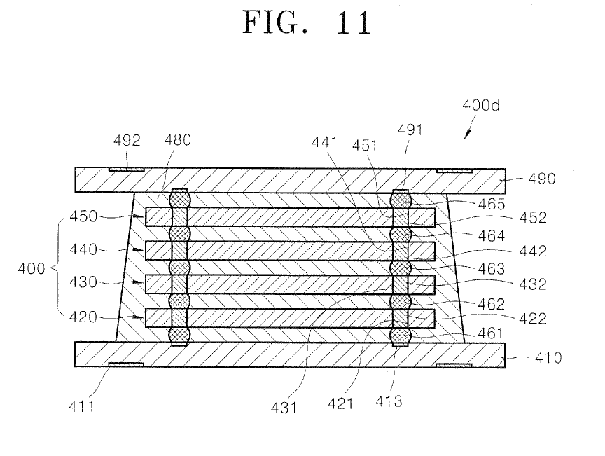

FIG. 10 is a cross-sectional view of a POP type semiconductor chip stack package according to an eighth embodiment of the present invention. Referring to FIG. 10, a semiconductor chip stack package 400c includes a first semiconductor package 403 and a second semiconductor package 404 stacked on the first semiconductor package 403. The first and second semiconductor packages 403 and 404 have the same structure as the semiconductor chip stack package 400a shown in FIG. 7. Second circuit patterns 492 of a reinforcing member 490a of the first semiconductor package 403 are flip-chip bonded and electrically connected to external connection terminals 412 of the second semiconductor package 404.

The first reinforcing member 490a arranged between the first semiconductor package 403 and the second semiconductor package 404 also serves as a connection member for electrically connecting the first semiconductor package 403 to the second semiconductor package 404 so that the semiconductor chips 420, 430, 440, and 450 of the first and second semiconductor packages 403 and 404 are connected to the substrate 410 of the first semiconductor package 403. The second semiconductor package 404 does not necessarily include the second reinforcing member 490b. As another example, the second semiconductor package 404 may be turned over so that the first semiconductor package 403 and the second semiconductor package 404 are stacked opposite each other. The second semiconductor package 404 may be stacked on the first semiconductor package 403 so that the reinforcing member 490a of the first semiconductor package 403 is brought into contact with the second circuit patterns 492 of the reinforcing member 490b of the second semiconductor package 404 directly or via conductive balls. Furthermore, the semiconductor chip stack package 400c may be stacked on a substrate on which is mounted a logic chip, as shown in FIG. 9.

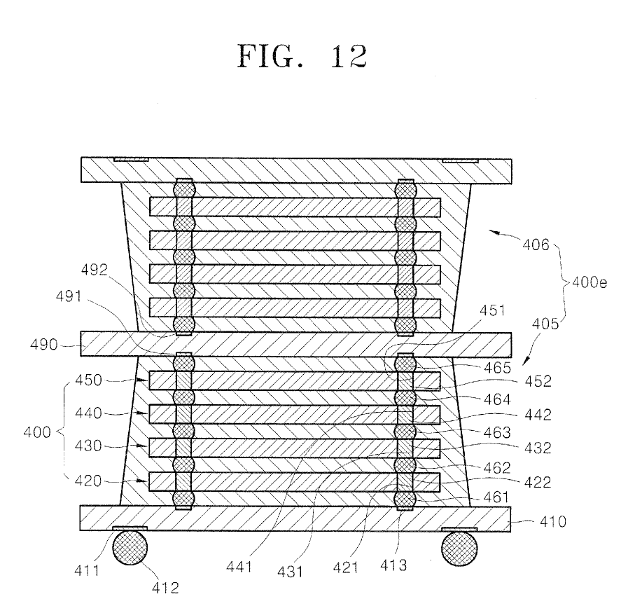

FIG. 11 is a cross-sectional view of an LGA type semiconductor chip stack package according to a ninth embodiment of the present invention. Referring to FIG. 11, a semiconductor chip stack package 400d is the same as the semiconductor chip stack package 400a of FIG. 7 except that it does not have the external connection terminals 412. The semiconductor chip stack package 400d is electrically connected to an external device via first circuit patterns 411. The semiconductor chip stack package 400d may be stacked on a substrate on which is mounted a logic chip, as shown in FIG. 9.

FIG. 12 is a cross-sectional view of a POP type semiconductor chip stack package according to a tenth embodiment of the present invention. Referring to FIG. 12, a semiconductor chip stack package 400e includes a first semiconductor package 405 and a second semiconductor package 406 stacked on the first semiconductor package 405. The first and second semiconductor packages 405 and 406 respectively have the same structures as the semiconductor chip stack packages 400a and 400d shown in FIGS. 7 and 11, and are vertically stacked opposite each other with a reinforcing member 490 interposed therebetween. In this case, the second semiconductor package 406 is connected to the second circuit patterns 492 of the reinforcing member 490 of the first semiconductor package 405 via connection members 465 without a reinforcing member. The second circuit patterns 492 of the reinforcing member 490 of the first semiconductor package 405 are arranged to correspond to the connection members 465.

The reinforcing member 490 of the first semiconductor package 405 serves as a connection member that not only prevents package warpage but also electrically connects the first semiconductor package 405 to the second semiconductor package 406. Furthermore, the semiconductor chip stack package 400e may be stacked on a substrate having a logic chip mounted thereon, as shown in FIG. 9.

As described above, the semiconductor chip stack package according to the embodiments of the present invention includes the reinforcing member made of a similar material as the substrate to prevent the package warpage, thus improving production yield and aiding the high integration of semiconductor devices. In addition, since the reinforcing member is used as a connection member when a semiconductor package is stacked on another semiconductor package, the semiconductor package can be smaller, slimmer and lighter.

According to an aspect of the present invention, there is provided a semiconductor chip stack package including a first substrate having first circuit patterns on one surface thereof; a first unit semiconductor chip including a plurality of semiconductor chips stacked vertically on the first substrate and including first connection pads electrically connected to the first circuit patterns of the first substrate on one surface thereof; and a first reinforcing member arranged over the first unit semiconductor chip and including first circuit patterns on one surface thereof. The top semiconductor chip in the first unit semiconductor chip further includes first subsidiary connection pads electrically connected to the first connection pads of the top semiconductor chip. The first circuit patterns of the first reinforcing member are electrically connected to the first circuit patterns of the first substrate via the first subsidiary connection pads of the top semiconductor chip.

The semiconductor chips other than the top semiconductor chip may include memory devices, and the top semiconductor chip may serve as a connection chip for connecting the other semiconductor chips to the first reinforcing member. The first subsidiary connection pads of the top semiconductor chip may be flip-chip bonded to the first circuit patterns of the first reinforcing member via conductive balls. The first circuit patterns of the substrate may be wire-bonded to the first connection pads of the first unit semiconductor chip via wires. The first substrate and the first reinforcing member may include a printed circuit substrate.

The package may further include a second substrate arranged under the first substrate and including third circuit patterns arranged on one surface thereof, fourth circuit patterns arranged on the other surface thereof, and third and fourth connection terminals respectively arranged on the third and fourth circuit patterns; and a logic chip mounted on the second substrate and connected to the fourth circuit patterns. The first circuit patterns of the first substrate may be flip-chip bonded to the fourth circuit patterns of the second substrate via the fourth connection terminals so that the first circuit patterns of the first reinforcing member are electrically connected to the logic chip.

The package may further include a second substrate arranged over the first reinforcing member and including third circuit patterns arranged on one surface thereof and fourth circuit patterns arranged on the other surface thereof; and a second unit semiconductor chip including a plurality of semiconductor chips stacked vertically on the second substrate and including second connection pads on one surface thereof, the second connection pads being electrically connected to the fourth circuit patterns of the second substrate. The first reinforcing member may further include second circuit patterns arranged on the other surface thereof. The second circuit patterns of the first reinforcing member may be electrically connected to the third circuit patterns of the second substrate. The second circuit patterns of the first reinforcing member may be flip-chip bonded to the third circuit patterns of the second substrate directly or via conductive balls. Alternatively, the second circuit patterns of the first reinforcing member may be electrically connected to second subsidiary connection pads of a top semiconductor chip in the second unit semiconductor chip. The second subsidiary connection pads of the top semiconductor chip may be directly flip-chip bonded to the second circuit patterns of the first reinforcing member.

The second connection pads of the second unit semiconductor chip may be wire-bonded to the fourth circuit patterns of the second substrate via wires. The package may further include third connection terminals arranged on the third circuit patterns of the second substrate; and a plurality of second chip connection terminals arranged on the second connection pads of the second unit semiconductor chip. The package may further include a second reinforcing member arranged over the second unit semiconductor chip and including third circuit patterns on one surface thereof. The top semiconductor chip in the second unit semiconductor chip may further include the second subsidiary connection pads connected to the second connection pads. The third circuit patterns of the second reinforcing member may be electrically connected to the third circuit patterns of the second substrate via the second subsidiary connection pads of the top semiconductor chip. Semiconductor chips other than the top semiconductor chip in the second unit semiconductor chip may include memory devices, and the top semiconductor chip may serve as a connection chip for connecting the other semiconductor chips to the second reinforcing member. The second subsidiary connection pads of the top semiconductor chip in the second unit semiconductor chip may be flip-chip bonded to the third circuit patterns of the second reinforcing member directly or via conductive balls. The second substrate and the second reinforcing member may include a printed circuit substrate.

According to another aspect of the present invention, there is provided a semiconductor chip stack package including a first substrate having first circuit patterns on one surface thereof; a first unit semiconductor chip including a plurality of semiconductor chips stacked vertically on the first substrate and including a plurality of first vias and first chip connection terminals buried in the first vias and electrically connected to the first circuit patterns of the first substrate; and a first reinforcing member arranged on the first unit semiconductor chip and including first circuit patterns on one surface thereof. The first circuit patterns of the first reinforcing member are electrically connected to the first circuit patterns of the first substrate via the first chip connection terminals of the first unit semiconductor chip.

The first chip connection terminals of the semiconductor chips in the first unit semiconductor chip may be flip-chip bonded directly or via conductive balls, the bottom semiconductor chip in the first unit semiconductor chip may be flip-chip bonded to the first circuit patterns of the first substrate directly or via conductive balls. The top semiconductor chip in the first unit semiconductor chip may be flip-chip bonded to the first circuit patterns of the first reinforcing member via conductive balls.

The package may further include a second substrate arranged over the first reinforcing member and including third circuit patterns arranged on one surface thereof, and a second unit semiconductor chip including a plurality of semiconductor chips stacked vertically on the second substrate and including second vias and second connection terminals buried in the second vias and electrically connected to the third circuit patterns of the second substrate. The first reinforcing member may further include second circuit patterns arranged on the other surface thereof, and the second circuit patterns of the first reinforcing member may be electrically connected to the fourth circuit patterns of the second substrate. The second circuit patterns of the first reinforcing member may be flip-chip bonded to the fourth circuit patterns of the second substrate directly or via conductive balls. The second circuit patterns of the first reinforcing member may be directly flip-chip bonded to the second chip connection terminals of the second unit semiconductor chip.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A semiconductor chip stack package comprising:
a first substrate including first circuit patterns on one surface thereof;
a first unit semiconductor chip including a plurality of semiconductor chips stacked vertically on the first substrate and including first connection pads electrically connected to the first circuit patterns of the first substrate; and
a first reinforcing member arranged over the first unit semiconductor chip and including first circuit patterns on one surface thereof, wherein:
a top semiconductor chip in the first unit semiconductor chip further includes first subsidiary connection pads connected to the first connection pads, and the first circuit patterns of the first reinforcing member are electrically connected to the first circuit patterns of the first substrate via the first subsidiary connection pads of the top semiconductor chip.

2. The package of claim 1, wherein the plurality of semiconductor chips in the first unit semiconductor chip other than the top semiconductor chip comprise memory devices, and wherein the top semiconductor chip is a connection chip connecting the other semiconductor chips to the first reinforcing member.

3. The package of claim 1, wherein the first subsidiary connection pads of the top semiconductor chip are flip-chip bonded to the first circuit patterns of the first reinforcing member via conductive balls.

4. The package of claim 1, wherein the first circuit patterns of the substrate are wire-bonded to the first connection pads of the first unit semiconductor chip via wires.

5. The package of claim 1, wherein the first substrate and the first reinforcing member comprise a printed circuit substrate.

6. The package of claim 1, further comprising:
a second substrate arranged under the first substrate and including third circuit patterns arranged on one surface thereof, fourth circuit patterns arranged on the other surface thereof, and third and fourth connection terminals respectively arranged on the third and fourth circuit patterns; and
a logic chip mounted on the second substrate and electrically connected to the fourth circuit patterns, wherein:
the first circuit patterns of the first substrate are flip-chip bonded to the fourth circuit patterns of the second substrate via the fourth connection terminals so that the first circuit patterns of the first reinforcing member are electrically connected to the logic chip.

7. The package of claim 1, further comprising:
a second substrate arranged over the first reinforcing member and including third circuit patterns arranged on one surface thereof and fourth circuit patterns arranged on the other surface thereof; and
a second unit semiconductor chip including a plurality of semiconductor chips stacked vertically on the second substrate and including second connection pads on one surface thereof, the second connection pads being electrically connected to the fourth circuit patterns of the second substrate, and wherein:
the first reinforcing member further includes second circuit patterns arranged on the other surface thereof, and
the second circuit patterns of the first reinforcing member are electrically connected to the third circuit patterns of the second substrate.

8. The package of claim 7, wherein the second circuit patterns of the first reinforcing member are flip-chip bonded to the third circuit patterns of the second substrate directly or via conductive balls.

9. The package of claim 7, wherein the second connection pads of the second unit semiconductor chip are wire-bonded to the fourth circuit patterns of the second substrate via wires.

10. The package of claim 7, further comprising a second reinforcing member arranged over the second unit semiconductor chip and including third circuit patterns on one surface thereof, wherein:
a top semiconductor chip in the second unit semiconductor chip further comprises second subsidiary connection pads electrically connected to the second connection pads and
the third circuit patterns of the second reinforcing member are electrically connected to the third circuit patterns of the second substrate via the second subsidiary connection pads of the top semiconductor chip.

11. The package of claim 10, wherein semiconductor chips other than the top semiconductor chip in the second unit semiconductor chip comprise memory devices and the top semiconductor chip is a connection chip connecting the other semiconductor chips to the second reinforcing member.

12. The package of claim 10, wherein the second substrate and the second reinforcing member comprise a printed circuit substrate.

13. The package of claim 1, further comprising:
a second substrate arranged over the first reinforcing member and including third circuit patterns arranged on one surface thereof and fourth circuit patterns arranged on the other surface thereof; and
a second unit semiconductor chip including a plurality of semiconductor chips stacked vertically on the second substrate and including second connection pads on one surface thereof, the second connection pads being electrically connected to the fourth circuit patterns of the second substrate, and wherein:
the first reinforcing member further includes second circuit patterns arranged on the other surface thereof,
the top semiconductor chip in the second unit semiconductor chip further comprises second subsidiary connection pads connected to the second connection pads, and
the second circuit patterns of the first reinforcing member are electrically connected to the second subsidiary connection pads of the top semiconductor chip in the second unit semiconductor chip.

14. The package of claim 13, wherein the second subsidiary connection pads of the top semiconductor chip of the second unit semiconductor chip are directly flip-chip bonded to the second circuit patterns of the first reinforcing member.

15. The package of claim 1, wherein the top semiconductor chip in the first unit semiconductor chip further includes:
a first insulating layer disposed on a surface of the top semiconductor chip comprising the first connection pads, the first insulating layer including first openings exposing portions of the first connection pads; and
a second insulating layer disposed on the first insulating layer and the first subsidiary connection pads, the second insulating layer including second openings exposing portions of the first subsidiary connection pads.

16. A semiconductor chip stack package comprising:
a first substrate including first circuit patterns on one surface thereof;
a first unit semiconductor chip including a plurality of semiconductor chips stacked vertically on the first substrate, each of the semiconductor chips including first vias and first chip connection terminals buried in the first vias and electrically connected to the first circuit patterns of the first substrate; and
a first reinforcing member arranged on the first unit semiconductor chip and including first circuit patterns on one surface thereof, wherein:
the first circuit patterns of the first reinforcing member are electrically connected to the first circuit patterns of the first substrate via the first chip connection terminals of the first unit semiconductor chip.

17. The package of claim 16, further comprising:
a second substrate arranged under the first substrate and including third circuit patterns arranged on one surface thereof, fourth circuit patterns arranged on the other surface thereof, and third and fourth connection terminals respectively arranged on the third and fourth circuit patterns; and
a logic chip mounted on the second substrate and connected to the fourth circuit patterns, wherein:
the first circuit patterns of the first substrate are flip-chip bonded to the fourth circuit patterns of the second substrate via the fourth connection terminals so that the first circuit patterns of the first reinforcing member are electrically connected to the logic chip.

18. The package of claim 16, further comprising:
a second substrate arranged over the first reinforcing member and including third circuit patterns arranged on one surface thereof, and
a second unit semiconductor chip including a plurality of semiconductor chips stacked vertically on the second substrate, each of the semiconductor chips including second vias and second chip connection terminals buried in the second vias and electrically connected to the third circuit patterns of the second substrate, and wherein:
the first reinforcing member further includes second circuit patterns arranged on the other surface thereof, and
the second circuit patterns of the first reinforcing member are electrically connected to the fourth circuit patterns of the second substrate.

19. The package of claim 18, wherein the second circuit patterns of the first reinforcing member are flip-chip bonded to the fourth circuit patterns of the second substrate directly or via conductive balls.

20. The package of claim 19, further comprising a second reinforcing member arranged over the second unit semiconductor chip and including third circuit patterns on one surface thereof, wherein the third circuit patterns of the second reinforcing member are electrically connected to the third circuit patterns of the second substrate via the second chip connection terminals of the second unit semiconductor chip.
